(19) United States
(12) Patent Application Publication
(10) Pub. No.: US 2026/0332742 A1
(43) Pub. Date: Oct. 22, 2026

(54) ABNORMALITY DETECTION CIRCUIT, ABNORMALITY DETECTION METHOD, AND IMAGING SYSTEM

(71) Applicant: Sony Semiconductor Solutions Corporation, Kanagawa (JP)

(72) Inventors: Tsuyoshi Nagao, Tokyo (JP); Kumiko Mahara, Kanagawa (JP)

(21) Appl. No.: 19/486,706

(22) PCT Filed: May 2, 2024
(86) PCT No.: PCT/JP2024/016908

§ 371 Date: Nov. 21, 2025

(30) Foreign Application Priority Data
Jun. 27, 2023 (JP) 2023-104877

(51) Int. Cl. H04N 17/00; G01R 31/28

(52) U.S. Cl. CPC H04N 17/002; G01R 31/2837

(57) ABSTRACT

An abnormality detection circuit according to one embodiment of the present disclosure includes a counter and a determination circuit. The counter is configured to, by performing a counting operation on a basis of pulses corresponding to a synchronization signal, detect a time length between two pulses corresponding to the synchronization signal. The determination circuit is configured to determine an abnormality in the synchronization signal on a basis of a count value of the counter.

### TECHNICAL FIELD

The present disclosure relates to an abnormality detection circuit that detects an abnormality in a circuit related to a synchronization signal, an abnormality detection method, and an imaging system.

### BACKGROUND ART

In an imaging apparatus, an imaging operation is performed on the basis of various control signals. For example, PTL 1 discloses an imaging apparatus that detects an abnormality in a pixel control signal that controls operation of a pixel.

### CITATION LIST

### Patent Literature

PTL 1: International Publication No. WO2017/209221

### SUMMARY OF THE INVENTION

Incidentally, in the imaging apparatus, an imaging operation is performed on the basis of a vertical synchronization signal and a horizontal synchronization signal. Therefore, it is desired to detect an abnormality in such synchronization signals.

It is desirable to provide an abnormality detection circuit that makes it possible to detect an abnormality in a synchronization signal, an abnormality detection method, and an imaging system.

An abnormality detection apparatus according to one embodiment of the present disclosure includes a counter and a determination circuit. The counter is configured to, by performing a counting operation on a basis of pulses corresponding to a synchronization signal, detect a time length between two pulses corresponding to the synchronization signal. The determination circuit is configured to determine an abnormality in the synchronization signal on a basis of a count value of the counter.

An abnormality detection method according to one embodiment of the present disclosure includes detecting, by performing a counting operation on a basis of pulses corresponding to a synchronization signal, a time length between two pulses corresponding to the synchronization signal; and determining an abnormality in the synchronization signal on a basis of a count value of the counting operation.

An imaging system according to one embodiment of the present disclosure includes an imaging apparatus and an image processing apparatus. The imaging apparatus is configured to perform an operation of imaging on a basis of a synchronization signal. The image processing apparatus is configured to perform image processing on a basis of a result of the imaging by the imaging apparatus. The image processing apparatus includes a counter and a determination circuit. The counter is configured to, by performing a counting operation on a basis of pulses corresponding to the synchronization signal, detect a time length between two pulses corresponding to the synchronization signal. The determination circuit is configured to determine an abnormality in the synchronization signal on a basis of a count value of the counter.

In the abnormality detection apparatus, the abnormality detection method, and the imaging system according to one embodiment of the present disclosure, by performing a counting operation on a basis of pulses corresponding to a synchronization signal, a time length between two pulses corresponding to the synchronization signal is detected. An abnormality in the synchronization signal is determined on a basis of a count value of the counting operation.

### BRIEF DESCRIPTION OF THE DRAWINGS

FIG. 1 is a block diagram illustrating a configuration example of an imaging system according to a first embodiment of the present disclosure.

FIG. 2 is a timing diagram illustrating an operation example of an abnormality detection circuit illustrated in FIG. 1.

FIG. 3 is another timing diagram illustrating an operation example of the abnormality detection circuit illustrated in FIG. 1.

FIG. 4 is a block diagram illustrating a configuration example of an imaging system according to a modification example of the first embodiment.

FIG. 5 is an explanatory diagram illustrating an example of a signal format of an image signal.

FIG. 6 is a timing diagram illustrating an operation example of an abnormality detection circuit according to the modification example of the first embodiment.

FIG. 7 is an explanatory diagram illustrating another example of the signal format of the image signal.

FIG. 8 is a timing diagram illustrating an operation example of an abnormality detection circuit according to another modification example of the first embodiment.

FIG. 9 is an explanatory diagram illustrating another example of the signal format of the image signal.

FIG. 10 is a timing diagram illustrating an operation example of an abnormality detection circuit according to another modification example of the first embodiment.

FIG. 11 is a block diagram illustrating a configuration example of an imaging system according to a second embodiment.

FIG. 12 is a timing diagram illustrating an operation example of an abnormality detection circuit illustrated in FIG. 11.

FIG. 13 is another timing diagram illustrating an operation example of the abnormality detection circuit illustrated in FIG. 11.

FIG. 14 is a timing diagram illustrating an operation example of an abnormality detection circuit according to a modification example of the second embodiment.

FIG. 15 is a timing diagram illustrating an operation example of an abnormality detection circuit according to another modification example of the second embodiment.

FIG. 16 is an explanatory diagram illustrating a configuration example of an inspection system according to an application example.

FIG. 17 is a block diagram depicting an example of schematic configuration of a vehicle control system.

FIG. 18 is a diagram of assistance in explaining an example of installation positions of an outside-vehicle information detecting section and an imaging section.

### MODES FOR CARRYING OUT THE INVENTION

Hereinafter, an embodiment of the present disclosure will be described in detail with reference to the drawings. It is to be noted that description is given in the following order.
1. First Embodiment
2. Second Embodiment
3. Application Example
4. Example of Practical Application to Mobile Body

### 1. First Embodiment

### [Configuration Example]

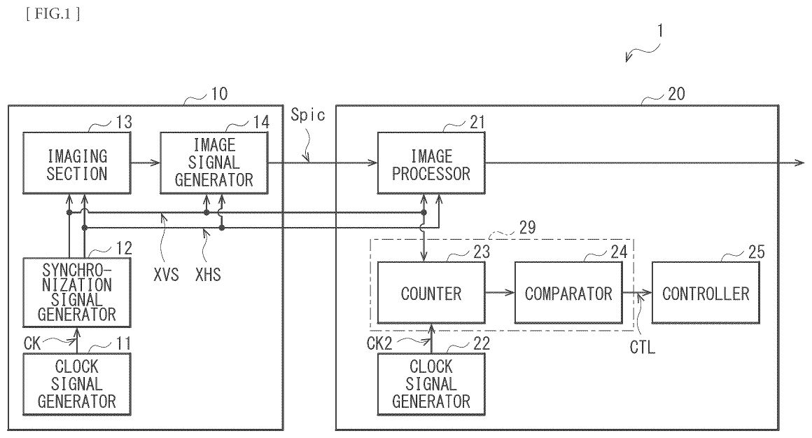

FIG. 1 illustrates a configuration example of an imaging system 1 including an abnormality detection circuit according to a first embodiment. Note that an abnormality detection method according to the embodiment of the present disclosure is embodied by the present embodiment and will be described together. The imaging system 1 includes an imaging apparatus 10 and an image processing apparatus 20.

The imaging apparatus 10 is what is called an image sensor and is configured to capture an image of a subject. The imaging apparatus 10 includes a clock signal generator 11, a synchronization signal generator 12, an imaging section 13, and an image signal generator 14.

The clock signal generator 11 is configured to generate a clock signal CK to be used in the imaging apparatus 10.

The synchronization signal generator 12 is configured to generate synchronization signals XVS and XHS on the basis of the clock signal CK. The synchronization signal XVS is what is called a vertical synchronization signal, and the synchronization signal XHS is what is called a horizontal synchronization signal.

The imaging section 13 includes, for example, a plurality of imaging pixels, and is configured to generate image data of a captured image by performing an imaging operation on the basis of the synchronization signals XVS and XHS.

The image signal generator 14 is configured to generate an image signal Spic using the synchronization signals XVS and XHS on the basis of the image data of the captured image supplied from the imaging section 13.

The imaging apparatus 10 captures an image of the subject with this configuration. Thereafter, the imaging apparatus 10 supplies the image signal Spic indicating the captured image and the synchronization signals XVS and XHS to the image processing apparatus 20.

The image processing apparatus 20 is configured to perform predetermined image processing on the captured image indicated by the image signal supplied from the imaging apparatus 10. The image processing apparatus 20 includes an image processor 21, a clock signal generator 22, a counter 23, a comparator 24, and a controller 25. The counter 23 and the comparator 24 constitute an abnormality detection circuit 29.

The image processor 21 is configured to perform predetermined image processing on the basis of the image signal Spic and the synchronization signals XVS and XHS supplied from the imaging apparatus 10. The image processor 21 outputs an image processing result.

The clock signal generator 22 is configured to generate a clock signal CK2 to be used in the image processing apparatus 20.

The counter 23 is configured to, by performing a counting operation OP of counting the number of clock pulses of the clock signal CK2 on the basis of pulses included in the synchronization signal XVS, detect a time length between two pulses included in the synchronization signal XVS. The counter 23 outputs a count value CNT during a period in which the counting operation OP is performed.

The comparator 24 is configured to compare the count value CNT of the counter 23 with a predetermined threshold value TH, and to generate a signal CTL indicating whether the count value CNT exceeds the threshold value TH.

The controller 25 is configured to control the operation of the image processing apparatus 20. Further, the controller 25 stops the operation of the image processing apparatus 20 on the basis of the signal CTL supplied from the comparator 24.

With this configuration, the abnormality detection circuit 29 including the counter 23 and the comparator 24 determines whether the pulses of the synchronization signal XVS appear at a predetermined interval corresponding to a time length of a frame period F. This makes it possible for the abnormality detection circuit 29 to detect an abnormality in the clock signal generator 11 or an abnormality in the synchronization signal generator 12 in the imaging apparatus 10.

Here, the abnormality detection circuit 29 corresponds to a specific example of an “abnormality detection circuit” in one embodiment of the present disclosure. The counter 23 corresponds to a specific example of a “counter” in one embodiment of the present disclosure. The comparator 24 corresponds to a specific example of a “determination circuit” in one embodiment of the present disclosure. The synchronization signal XVS corresponds to a specific example of a “synchronization signal” in one embodiment of the present disclosure.

### [Operation and Workings]

Next, an operation and workings of the imaging system 1 according to the present embodiment will now be described.

### (Overview of Overall Operation)

First, an overview of the overall operation of the imaging system 1 will be described with reference to FIG. 1. The clock signal generator 11 of the imaging apparatus 10 generates the clock signal CK to be used in the imaging apparatus 10. The synchronization signal generator 12 generates the synchronization signals XVS and XHS on the basis of the clock signal CK. The imaging section 13 generates the image data of the captured image by performing the imaging operation on the basis of the synchronization signals XVS and XHS. The image signal generator 14 is configured to generate the image signal Spic using the synchronization signals XVS and XHS on the basis of the image data of the captured image supplied from the imaging section 13.

The image processor 21 of the image processing apparatus 20 performs the predetermined image processing on the basis of the image signal Spic and the synchronization signals XVS and XHS supplied from the imaging apparatus 10. The clock signal generator 22 generates the clock signal CK2 to be used in the image processing apparatus 20. The counter 23 of the abnormality detection circuit 29 detects the time length between two pulses included in the synchronization signal XVS by starting the counting operation OP of counting the number of clock pulses of the clock signal CK2 on the basis of the pulse included in the synchronization signal XVS. The counter 23 outputs the count value CNT during the period in which the counting operation OP is performed. The comparator 24 of the abnormality detection circuit 29 compares the count value CNT of the counter 23 with the predetermined threshold value TH, and generates the signal CTL indicating whether the count value CNT exceeds the threshold value TH. The controller 25 is configured to control the operation of the image processing apparatus 20. The controller 25 stops the operation of the image processing apparatus 20 on the basis of the signal CTL supplied from the comparator 24.

### (Detailed Operation)

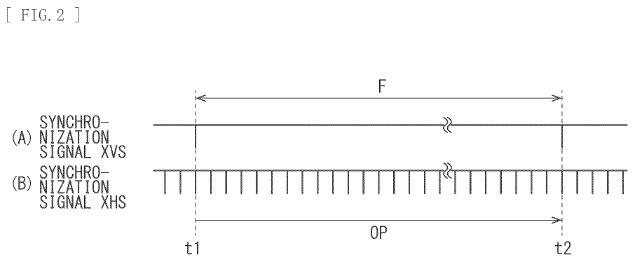

FIG. 2 illustrates an operation example of the abnormality detection circuit 29. (A) illustrates a waveform of the synchronization signal XVS, and (B) illustrates a waveform of the synchronization signal XHS. At timing t1, a pulse appears on the synchronization signal XVS (FIG. 2(A)). As a result, the frame period F starts. Thereafter, the counter 23 starts the counting operation OP on the basis of this pulse. Thereafter, at timing t2, a second pulse appears on the synchronization signal XVS (FIG. 2(A)). As a result, the frame period F ends, and a new frame period F starts. The counter 23 stops the counting operation OP on the basis of this pulse. In the counting operation OP, the comparator 24 determines whether the count value CNT has exceeded the threshold value TH. The threshold value TH is set to such a value that, in a case where the pulses of the synchronization signal XVS appear at the predetermined interval corresponding to the time length of the frame period F, the count value CNT does not exceed the threshold value TH.

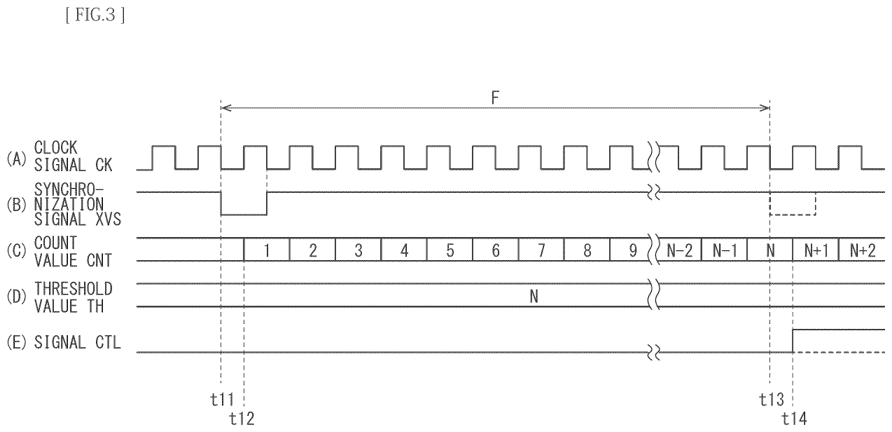

FIG. 3 illustrates a more detailed operation example of the abnormality detection circuit 29 in a case where the second pulse does not appear on the synchronization signal XVS. (A) illustrates a waveform of the clock signal CK, (B) illustrates a waveform of the synchronization signal XVS, (C) illustrates the count value CNT of the counter 23, (D) illustrates the threshold value TH of the comparator 24, and (E) illustrates a waveform of the signal CTL. In FIG. 3, (B) and (E) use broken lines to indicate the signals of a case where the second pulse appears on the synchronization signal XVS. Timing t11 and timing t13 in FIG. 3 respectively correspond to the timing t1 and the timing t2 in FIG. 2.

In the imaging apparatus 10, the synchronization signal generator 12 generates the synchronization signal XVS on the basis of the clock signal CK generated by the clock signal generator 11 (FIG. 3(A) and (B)).

When a pulse appears on the synchronization signal XVS at the timing t11 (FIG. 3(B)), in the image processing apparatus 20, the counter 23 starts the counting operation OP on the basis of this pulse at, for example, timing t12, and the count value CNT of the counter 23 starts to increase (FIG. 3(C)). In this example, the threshold value TH is “N” (FIG. 3(D)). In a case where the count value CNT is less than or equal to the threshold value TH, the signal CTL is maintained at a low level (FIG. 3(E)).

For example, in a case where the imaging system 1 is operating normally, a pulse appears on the synchronization signal XVS at the timing t13 (FIG. 3(B)). The counter 23 stops the counting operation OP on the basis of this pulse. For example, the counter 23 may stop the counting operation OP by stopping an incrementing operation of the count value CNT, or may stop the counting operation OP by resetting the count value CNT. In a case where the count value CNT is reset, the counter 23 may immediately start the next counting operation OP.

At the timing t13, the count value CNT is “N”. In this example, the counter 23 stops the counting operation OP, and thus the count value CNT does not exceed the threshold value TH (“N”).

For example, in a case where the clock signal generator 11 or the synchronization signal generator 12 in the imaging apparatus 10 fails after the timing t11, no pulse appears on the synchronization signal XVS at the timing t13. In this case, the count value CNT of the counter 23 continues to increase (FIG. 3(C)). At timing t14, when the count value CNT becomes “N+1”, the count value CNT exceeds the threshold value TH (“N”). Thus, the comparator 24 changes the signal CTL from the low level to the high level (FIG. 3(E)).

The controller 25 stops the operation of the image processing apparatus 20 on the basis of the change in the signal CTL. That is, the operation of the image processing apparatus 20 is stopped because, for example, an abnormality has occurred in the clock signal generator 11 or in the synchronization signal generator 12 in the imaging apparatus 10.

As described above, the abnormality detection circuit 29 is provided with the counter 23 and the comparator 24. The counter 23 is configured to, by performing the counting operation OP on the basis of the pulses corresponding to the synchronization signal XVS, detect the time length between two pulses corresponding to the synchronization signal XVS. The comparator 24 is configured to determine an abnormality in the synchronization signal XVS on the basis of the count value CNT of the counter 23. Thus, it is possible for the abnormality detection circuit 29 to detect, for example, an abnormality in the synchronization signal XVS caused due to a failure of the clock signal generator 11 or the synchronization signal generator 12 in the imaging apparatus 10.

Additionally, in the abnormality detection circuit 29, the counter 23 is configured to start the counting operation OP on the basis of a first pulse of the two pulses, and to stop the counting operation OP on the basis of a second pulse of the two pulses. The comparator 24 is configured to determine an abnormality by determining whether the count value CNT exceeds the predetermined threshold value TH. Therefore, for example, in a case where the circuit that generates the synchronization signal XVS fails in the middle of operation, the circuit does not generate the second pulse after generating the first pulse. The count value CNT therefore exceeds the threshold value TH. As a result, it is possible for the abnormality detection circuit 29 to detect an abnormality in the synchronization signal XVS.

Further, in the abnormality detection circuit 29, the synchronization signal XVS includes the first pulse and the second pulse. Thus, it is possible for the abnormality detection circuit 29 to directly detect an abnormality in the synchronization signal XVS on the basis of the two pulses in the synchronization signal XVS.

### [Effects]

As described above, in the present embodiment, the counter and the comparator are provided. The counter is configured to, by performing the counting operation on the basis of the pulses corresponding to the synchronization signal, detect the time length between two pulses corresponding to the synchronization signal. The comparator is configured to determine an abnormality in the circuit that generates the synchronization signal on the basis of the count value of the counter. It is therefore possible to detect an abnormality in the synchronization signal.

In the present embodiment, the counter is configured to start the counting operation on the basis of the first pulse of the two pulses, and to stop the counting operation on the basis of the second pulse of the two pulses. The comparator is configured to determine an abnormality by determining whether the count value has exceeded the predetermined threshold value. This makes it possible to detect an abnormality in the synchronization signal.

In the present embodiment, it is possible to detect an abnormality in the synchronization signal because the synchronization signal includes the first pulse and the second pulse.

### [Modification Example 1-1]

Although whether the pulses of the synchronization signal XVS appear at the predetermined interval corresponding to the length of the frame period F is directly detected in the above-described embodiment, the present disclosure is not limited thereto. Instead, for example, whether the pulses of the synchronization signal XVS appear at the predetermined interval corresponding to the length of the frame period F may be detected indirectly. Hereafter, the present modification example will be described in detail with some examples.

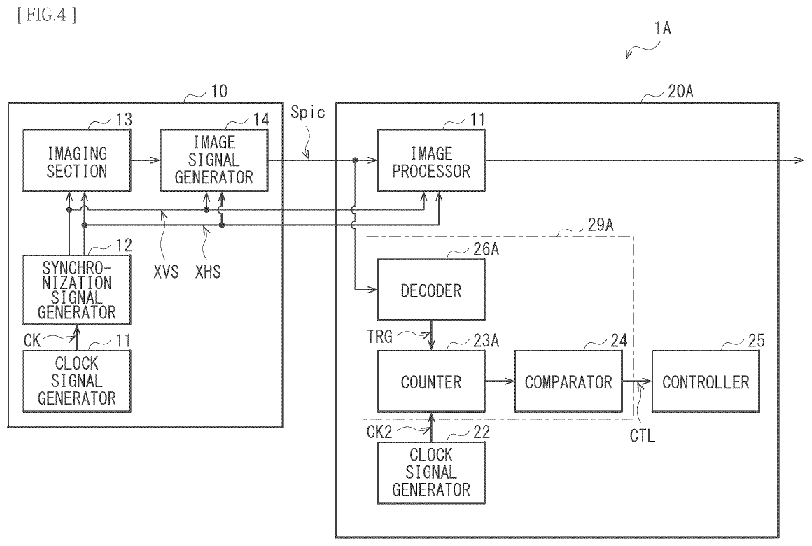

FIG. 4 illustrates a configuration example of an imaging system 1 A according to the present modification example. The imaging system 1A includes an image processing apparatus 20A. The image processing apparatus 20A includes a decoder 26A and a counter 23A. In this example, the imaging apparatus 10 and the image processing apparatus 20A perform communication using an SLVS-EC (Scalable Low Voltage Signaling with Embedded Clock) interface. The decoder 26A, the counter 23A, and the comparator 24 constitute an abnormality detection circuit 29A.

The decoder 26A is configured to detect control data included in the image signal Spic and indicating a frame beginning, and to generate a trigger signal TRG on the basis of the control data.

The counter 23A is configured to, by performing the counting operation OP of counting the number of clock pulses of the clock signal CK2 on the basis of the pulses included in the trigger signal TRG, detect a time length between two pulses included in the trigger signal TRG.

FIG. 5 illustrates an example of a signal format of the image signal Spic in a case where the SLVS-EC interface is used. The image signal Spic includes a plurality of packets. Each of the packets includes a packet header PH, data, and a packet footer PF. The plurality of packets includes a packet including blank data and a packet including effective data. The plurality of packets is transmitted in synchronization with the synchronization signal XHS. The packet header PH of the first packet out of the plurality of packets in one frame period F includes the control data indicating the frame beginning.

Here, the abnormality detection circuit 29A corresponds to a specific example of an “abnormality detection circuit” in one embodiment of the present disclosure. The decoder 26A corresponds to a specific example of a “decoder” in one embodiment of the present disclosure. The counter 23A corresponds to a specific example of a “counter” in one embodiment of the present disclosure. The image signal Spic corresponds to a specific example of an “image signal” in one embodiment of the present disclosure. The frame period F corresponds to a specific example of a “cycle period” in one embodiment of the present disclosure.

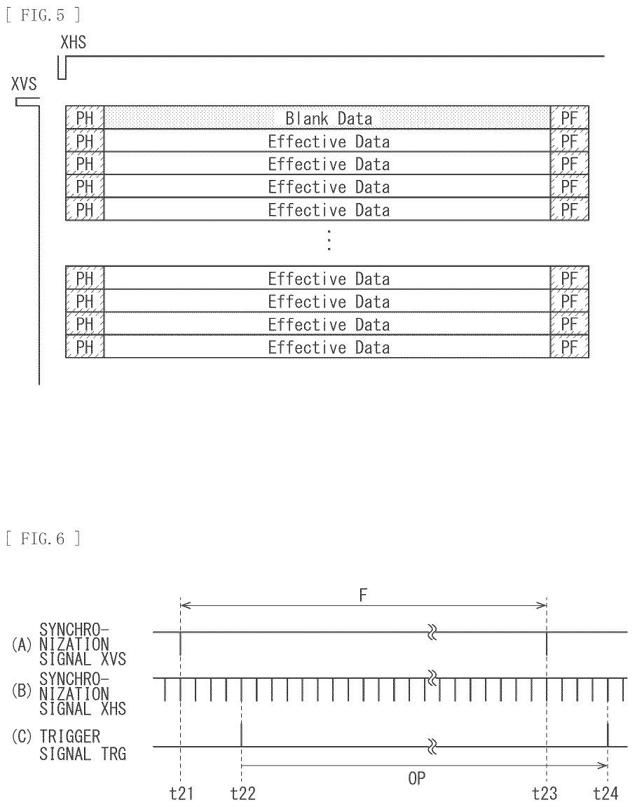

FIG. 6 illustrates an operation example of the abnormality detection circuit 29A in a case where the SLVS-EC interface is used. (A) illustrates a waveform of the synchronization signal XVS, (B) illustrates a waveform of the synchronization signal XHS, and (C) illustrates a waveform of the trigger signal TRG.

At timing t21, a pulse appears on the synchronization signal XVS (FIG. 6(A)). As a result, the frame period F starts. At timing t22, the decoder 26A detects the control data included in the image signal Spic and indicating the frame beginning, and generates a pulse of the trigger signal TRG on the basis of the control data (FIG. 6(C)). The counter 23A starts the counting operation OP on the basis of this pulse.

Thereafter, at timing t23, a second pulse appears on the synchronization signal XVS (FIG. 6(A)). As a result, the frame period F ends, and a new frame period F starts. At timing t24, the decoder 26A detects the control data included in the image signal Spic and indicating the frame beginning, and generates a pulse of the trigger signal TRG on the basis of the control data (FIG. 6(C)). The counter 23A stops the counting operation OP on the basis of this pulse. In the counting operation OP, the comparator 24 determines whether the count value CNT has exceeded the threshold value TH.

The abnormality detection circuit 29A detects the time length between two pulses in the trigger signal TRG generated by the decoder 26A. Specifically, the abnormality detection circuit 29A detects a time length between pieces of control data indicating the frame beginning of the two respective frame periods F adjacent to each other. Accordingly, it is possible for the abnormality detection circuit 29A to indirectly detect whether the pulses of the synchronization signal XVS appear at the predetermined interval corresponding to the length of the frame period F.

Next, description is given of another imaging system 1A according to the present modification example. In this example, the imaging apparatus 10 and the image processing apparatus 20A perform communication using an SLVS interface. The decoder 26A of the imaging system 1A is configured to detect the control data included in the image signal Spic and attached to the effective data, and to generate the trigger signal TRG on the basis of the control data.

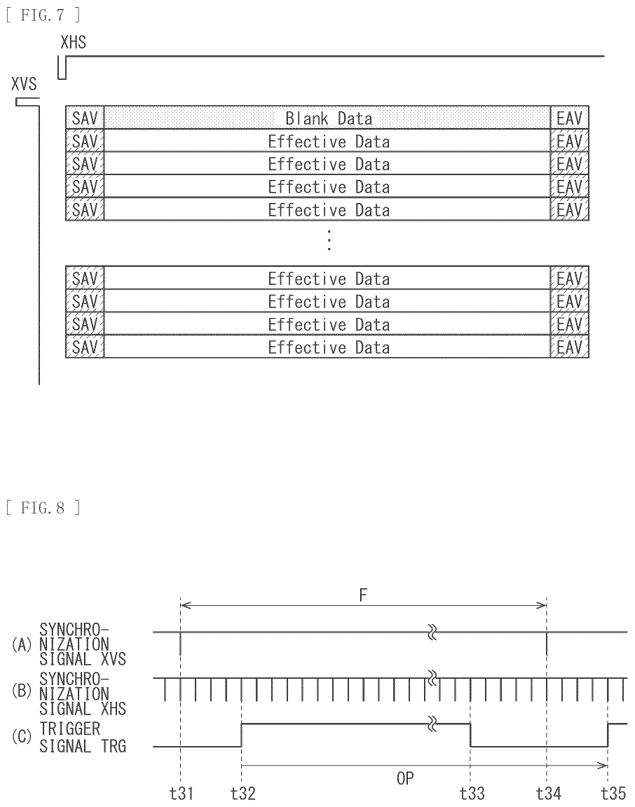

FIG. 7 illustrates an example of the signal format of the image signal Spic in a case where the SLVS interface is used. The image signal Spic includes a plurality of packets. Each of the packets includes a packet header SAV, data, and a packet footer EAV. The plurality of packets includes a packet including blank data and a packet including effective data. The plurality of packets is transmitted in synchronization with the synchronization signal XHS. The packet header SAV of the packet including the effective data includes the control data indicating that the packet includes the effective data.

FIG. 8 illustrates an operation example of the abnormality detection circuit 29A in a case where the SLVS interface is used. (A) illustrates a waveform of the synchronization signal XVS, (B) illustrates a waveform of the synchronization signal XHS, and (C) illustrates a waveform of the trigger signal TRG.

At timing t31, a pulse appears on the synchronization signal XVS (FIG. 8(A)). As a result, the frame period F starts. At timing t32, the decoder 26A detects the control data included in the image signal Spic and indicating that the packet includes the effective data. The decoder 26A changes the trigger signal TRG from a low level to a high level on the basis of the control data (FIG. 8(C)). The counter 23A starts the counting operation OP on the basis of the change in the trigger signal TRG. In this example, in the period from the timing t32 to timing t33, each of the packets in the image signal Spic includes the control data indicating that the effective data is included, and thus the decoder 26A maintains the trigger signal TRG at the high level during this period. Thereafter, at the timing t33, when the packet no longer includes the effective data, the decoder 26A changes the trigger signal TRG from the high level to the low level.

Thereafter, at timing t34, a second pulse appears on the synchronization signal XVS (FIG. 6(A)). As a result, the frame period F ends, and a new frame period F starts. At timing t35, the decoder 26A detects the control data included in the image signal Spic and indicating that the packet includes the effective data. The decoder 26A changes the trigger signal TRG from the low level to the high level on the basis of the control data (FIG. 8(C)). The counter 23A stops the counting operation OP on the basis of the change in the trigger signal TRG. In the counting operation OP, the comparator 24 determines whether the count value CNT has exceeded the threshold value TH.

The abnormality detection circuit 29A detects the time length between two pulses in the trigger signal TRG generated by the decoder 26A. Specifically, the abnormality detection circuit 29A detects a time length between effective data start timings of the two respective frame periods F that are adjacent to each other. Accordingly, it is possible for the abnormality detection circuit 29A to indirectly detect whether the pulses of the synchronization signal XVS appear at the predetermined interval corresponding to the length of the frame period F.

Next, description is given of another imaging system 1A according to the present modification example. In this example, the imaging apparatus 10 and the image processing apparatus 20A perform communication using an MIPI (Mobile Industry Processor Interface). The decoder 26A of the imaging system 1A is configured to detect the control data included in the image signal Spic and indicating the frame beginning, and to generate the trigger signal TRG on the basis of the control data.

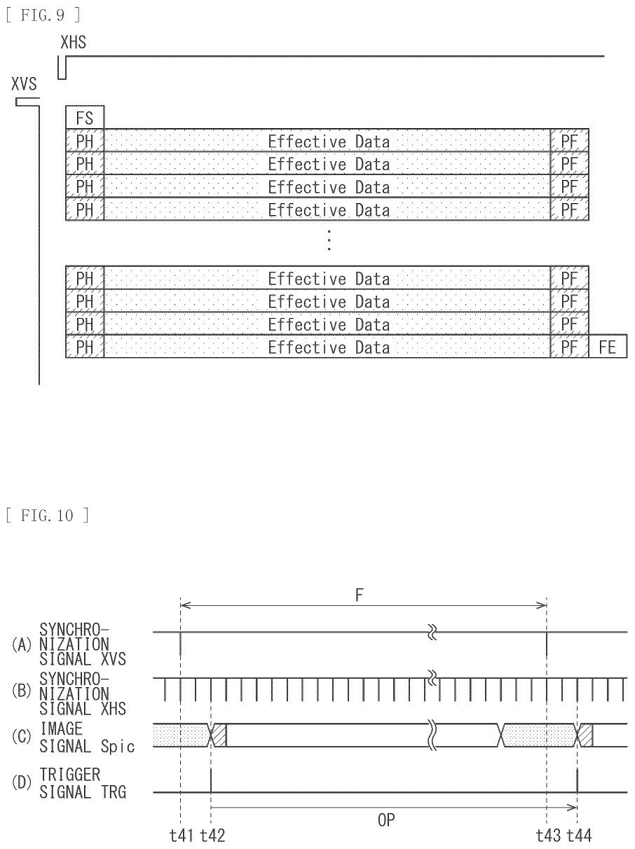

FIG. 9 illustrates an example of the signal format of the image signal Spic in a case where the MIPI is used. The image signal Spic includes a plurality of packets. Each of the packets includes the packet header PH, data, and the packet footer PF. The plurality of packets is transmitted in synchronization with the synchronization signal XHS. A plurality of packets in one frame period F is provided between the control data (a frame start FS) indicating the frame beginning and the control data (a frame end FE) indicating the end of the frame.

FIG. 10 illustrates an operation example of the abnormality detection circuit 29A in a case where the MIPI is used. (A) illustrates a waveform of the synchronization signal XVS, (B) illustrates a waveform of the synchronization signal XHS, (C) illustrates a waveform of the image signal Spic, and (D) illustrates a waveform of the trigger signal TRG.

At timing t41, a pulse appears on the synchronization signal XVS (FIG. 10(A)). As a result, the frame period F starts. At timing t42, a short packet indicating the frame beginning appears on the image signal Spic (FIG. 10(C)). The short packet includes the control data indicating the frame start FS illustrated in FIG. 9. The decoder 26A generates a pulse of the trigger signal TRG on the basis of the control data included in the short packet (FIG. 10(D)). The counter 23A starts the counting operation OP on the basis of this pulse.

Thereafter, at timing t43, a second pulse appears on the synchronization signal XVS (FIG. 6(A)). As a result, the frame period F ends, and a new frame period F starts. At timing t44, a short packet indicating the frame beginning appears on the image signal Spic (FIG. 10(C)). The decoder 26A generates a pulse of the trigger signal TRG on the basis of the control data included in the short packet (FIG. 10(D)). The counter 23A stops the counting operation OP on the basis of this pulse. In the counting operation OP, the comparator 24 determines whether the count value CNT has exceeded the threshold value TH.

The abnormality detection circuit 29A detects the time length between two pulses in the trigger signal TRG generated by the decoder 26A. Specifically, the abnormality detection circuit 29A detects a time length between the short packets indicating the frame beginning of the two respective frame periods F adjacent to each other. Accordingly, it is possible for the abnormality detection circuit 29A to indirectly detect whether the pulses of the synchronization signal XVS appear at the predetermined interval corresponding to the length of the frame period F.

As described above, the abnormality detection circuit 29A according to the present modification example further includes the decoder 26A configured to decode the control data included in the image signal Spic corresponding to the synchronization signal XVS and provided at a predetermined timing position in a frame period corresponding to one cycle of the synchronization signal XVS. The decoder 26A is configured to generate the first pulse on the basis of the control data in a first frame period F, and is configured to generate the second pulse on the basis of the control data in a second frame period F after the first frame period F. Accordingly, it is possible for the abnormality detection circuit 29A to indirectly detect an abnormality in the synchronization signal XVS on the basis of the two pulses generated by the decoder 26A.

### [Modification Example 1-2]

Although an abnormality in the synchronization signal XVS is detected in the above-described embodiment, the present disclosure is not limited thereto. Instead, for example, an abnormality in the synchronization signal XHS may be detected.

### 2. Second Embodiment

Next, description is given of an imaging system 2 according to a second embodiment. The present embodiment is different from the first embodiment in a period in which the time length is detected. That is, the time length of the frame period F is detected in the first embodiment, but a time length of a response time of the imaging apparatus to the synchronization signal XVS is detected in the present embodiment. Note that the components substantially the same as those of the imaging system 1 according to the first embodiment are denoted by the same reference numerals, and description thereof will be omitted as appropriate.

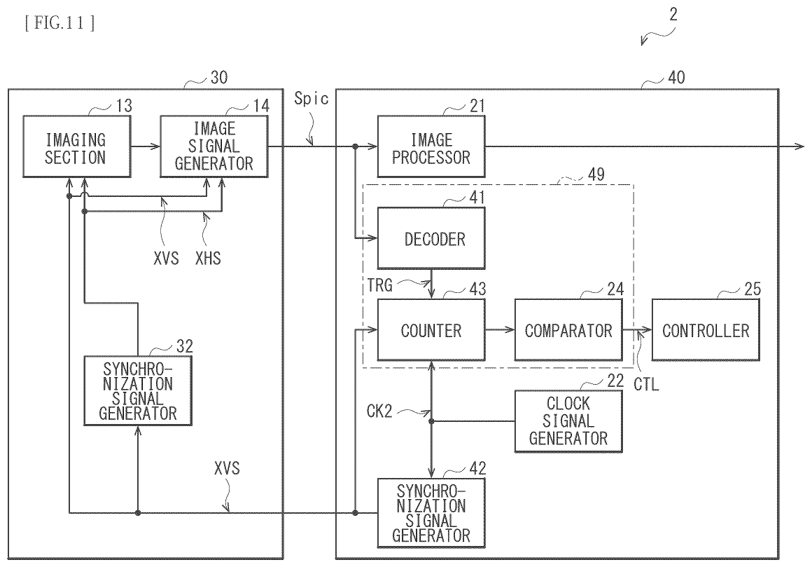

FIG. 11 illustrates a configuration example of the imaging system 2. The imaging system 2 includes an imaging apparatus 30 and an image processing apparatus 40. In this example, the imaging apparatus 30 and the image processing apparatus 40 perform communication using the SLVS-EC interface. The image signal Spic has the signal format illustrated in FIG. 5.

The imaging apparatus 30 is configured to capture an image of a subject on the basis of the synchronization signal XVS supplied from the image processing apparatus 40. The imaging apparatus 30 includes a synchronization signal generator 32. The synchronization signal generator 32 is configured to generate the synchronization signal XHS on the basis of the synchronization signal XVS supplied from the image processing apparatus 40.

The image processing apparatus 40 includes a decoder 41, a synchronization signal generator 42, and a counter 43. The decoder 41, the counter 43, and the comparator 24 constitute an abnormality detection circuit 49.

The decoder 41 is configured to detect the control data included in the image signal Spic and indicating the frame beginning, and to generate the trigger signal TRG on the basis of the control data.

The synchronization signal generator 42 is configured to generate the synchronization signal XVS on the basis of the clock signal CK2 generated by the clock signal generator 22. The image processing apparatus 40 supplies the synchronization signal XVS generated by the synchronization signal generator 42 to the imaging apparatus 30.

The counter 43 is configured to detect a time length between the pulse of the synchronization signal XVS and the pulse of the trigger signal TRG by starting the counting operation OP of counting the number of clock pulses of the clock signal CK2 supplied from the clock signal generator 22 on the basis of the pulse included in the synchronization signal XVS.

Here, the abnormality detection circuit 49 corresponds to a specific example of an “abnormality detection circuit” in one embodiment of the present disclosure. The decoder 41 corresponds to a specific example of a “decoder” in one embodiment of the present disclosure. The synchronization signal generator 42 corresponds to a specific example of a “synchronization signal generation circuit” in one embodiment of the present disclosure.

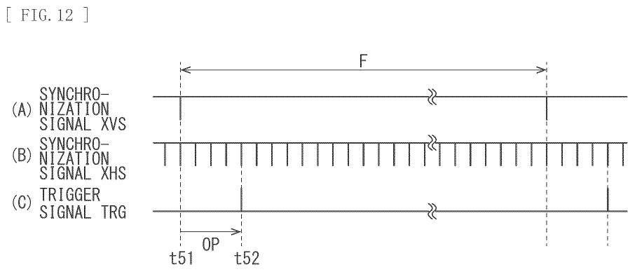

FIG. 12 illustrates an operation example of the abnormality detection circuit 49. (A) illustrates a waveform of the synchronization signal XVS, (B) illustrates a waveform of the synchronization signal XHS, and (C) illustrates a waveform of the trigger signal TRG. At timing t51, a pulse appears on the synchronization signal XVS (FIG. 12(A)). As a result, the frame period F starts. The counter 43 starts the counting operation OP on the basis of this pulse. Thereafter, at timing t52, the decoder 41 detects the control data included in the image signal Spic and indicating the frame beginning, and generates a pulse of the trigger signal TRG on the basis of the control data (FIG. 12(C)). The counter 43 stops the counting operation OP on the basis of this pulse. In the counting operation OP, the comparator 24 determines whether the count value CNT has exceeded the threshold value TH. The threshold value TH is set to such a value that the count value CNT does not exceed the threshold value TH in a case where the response time of the imaging apparatus 30 is a normal time. The response time is from the timing of the pulse on the synchronization signal XVS until when the imaging apparatus 30 generates the control data indicating the frame beginning.

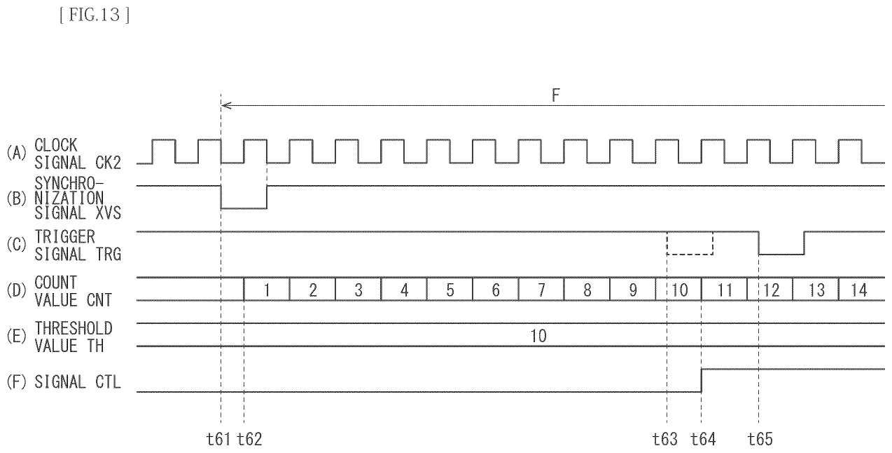

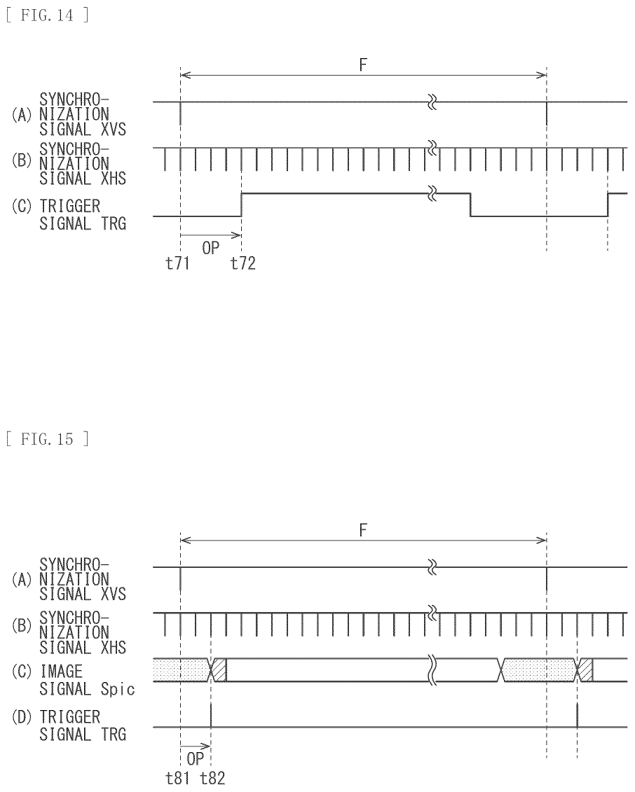

FIG. 13 illustrates a more detailed operation example of the abnormality detection circuit 49 in a case where the pulse of the trigger signal TRG is delayed. (A) illustrates a waveform of the clock signal CK2, (B) illustrates a waveform of the synchronization signal XVS, (C) illustrates a waveform of the trigger signal TRG, (D) illustrates the count value CNT of the counter 43, (E) illustrates the threshold value TH of the comparator 24, and (F) illustrates a waveform of the signal CTL.

In the imaging apparatus 30, the synchronization signal generator 42 generates the synchronization signal XVS on the basis of the clock signal CK2 generated by the clock signal generator 22 (FIG. 13(A) and (B)).

At timing t61, when a pulse appears on the synchronization signal XVS (FIG. 13(B)), the counter 43 in the image processing apparatus 40 starts the counting operation OP on the basis of this pulse, for example, at timing t62, and the count value CNT of the counter 43 starts to increase (FIG. 13(D)). In this example, the threshold value TH is “10” (FIG. 13(E)). In a case where the count value CNT is less than or equal to the threshold value TH, the signal CTL is maintained at the low level (FIG. 13(F)).

For example, in a case where the imaging system 2 is operating normally, at timing t63, the decoder 41 detects the control data included in the image signal Spic and indicating the frame beginning, and generates a pulse of the trigger signal TRG on the basis of the control data (FIG. 13(C)). The counter 43 stops the counting operation OP on the basis of this pulse.

At the timing t63, the count value CNT is “10”. In this example, the counter 43 stops the counting operation OP, and thus the count value CNT does not exceed the threshold value TH (“10”).

For example, in a case where an abnormality occurs in the signal path of the synchronization signal XVS from the image processing apparatus 40 to the imaging apparatus 30 or a failure occurs in the image signal generator 14 of the imaging apparatus 30, the timing at which the pulse appears on the trigger signal TRG can be delayed from the timing t63. In this case, the count value CNT of the counter 43 continues to increase (FIG. 13(D)). At timing t64, when the count value CNT becomes “11”, the count value CNT exceeds the threshold value TH (“10”). Thus, the comparator 24 changes the signal CTL from the low level to the high level (FIG. 13(F)).

The controller 25 stops the operation of the image processing apparatus 40 on the basis of the change in the signal CTL. That is, the operation of the image processing apparatus 40 is stopped because an abnormality has occurred in the signal path of the synchronization signal XVS from the image processing apparatus 40 to the imaging apparatus 30 or a failure has occurred in the image signal generator 14 of the imaging apparatus 30.

As described above, the abnormality detection circuit 49 is provided with the counter 43 and the comparator 24. The counter 43 is configured to, by performing the counting operation OP on the basis of the pulses corresponding to the synchronization signal XVS, detect the time length between two pulses corresponding to the synchronization signal XVS. The comparator 24 is configured to determine an abnormality in the synchronization signal XVS on the basis of the count value CNT of the counter 43. Thus, it is possible for the abnormality detection circuit 49 to detect, for example, an abnormality in the synchronization signal XVS caused due to an abnormality in the signal path of the synchronization signal XVS from the image processing apparatus 40 to the imaging apparatus 30 or a failure of the image signal generator 14 in the image processing apparatus 40.

The abnormality detection circuit 49 further includes the synchronization signal generator 42 and the decoder 41. The synchronization signal generator 42 is configured to generate the synchronization signal XVS. The decoder 41 is configured to decode the control data included in the image signal Spic corresponding to the synchronization signal XVS and provided at the predetermined timing position in the frame period F corresponding to one cycle of the synchronization signal XVS. The synchronization signal XVS includes the first pulse. The decoder 41 is configured to generate the second pulse on the basis of the control data. Thus, it is possible for the abnormality detection circuit 49 to detect, for example, an abnormality in the synchronization signal XVS caused due to an abnormality in the signal path of the synchronization signal XVS from the image processing apparatus 40 to the imaging apparatus 30 or a failure of the image signal generator 14 in the imaging apparatus 30. Other effects are similar to those in the case of the first embodiment described above.

### [Modification Example 2-1]

Although the imaging apparatus 30 and the image processing apparatus 40 perform communication using the SLVS-EC interface in the above-described embodiment, the present disclosure is not limited thereto. Instead, for example, the communication may be performed using the SLVS interface or using the MIPI.

FIG. 14 illustrates an operation example of the abnormality detection circuit 49 in a case where the SLVS interface is used. (A) illustrates a waveform of the synchronization signal XVS, (B) illustrates a waveform of the synchronization signal XHS, and (C) illustrates a waveform of the trigger signal TRG.

At timing t71, a pulse appears on the synchronization signal XVS (FIG. 14(A)). As a result, the frame period F starts. The counter 43 starts the counting operation OP on the basis of this pulse. Thereafter, at timing t32, the decoder 41 detects the control data included in the image signal Spic and indicating that the packet includes the effective data, and changes the trigger signal TRG from the low level to the high level on the basis of the control data (FIG. 14(C)). The counter 43 stops the counting operation OP on the basis of the change in the trigger signal TRG. In the counting operation OP, the comparator 24 determines whether the count value CNT has exceeded the threshold value TH.

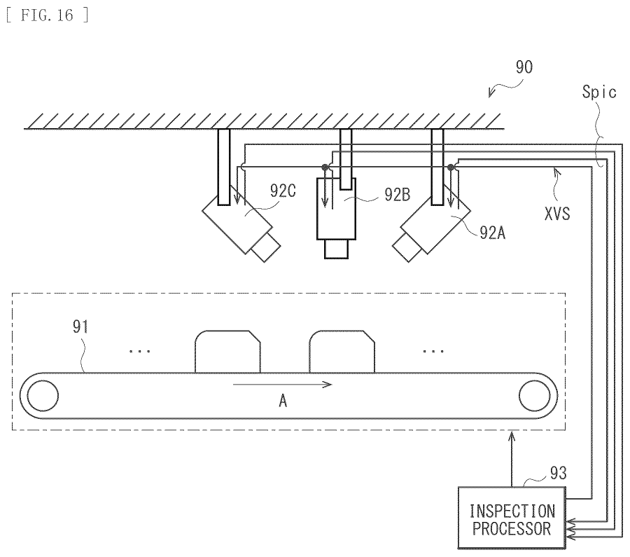

FIG. 15 illustrates an operation example of the abnormality detection circuit 49 in a case where the MIPI is used. (A) illustrates a waveform of the synchronization signal XVS, (B) illustrates a waveform of the synchronization signal XHS, (C) illustrates a waveform of the image signal Spic, and (D) illustrates a waveform of the trigger signal TRG.

At timing t81, a pulse appears on the synchronization signal XVS (FIG. 15(A)). As a result, the frame period F starts. The counter 43 starts the counting operation OP on the basis of this pulse. At timing t82, a short packet indicating the frame beginning appears on the image signal Spic (FIG. 15(C)). The decoder 41 generates a pulse of the trigger signal TRG on the basis of the control data included in the short packet (FIG. 15(D)). The counter 43 stops the counting operation OP on the basis of this pulse. In the counting operation OP, the comparator 24 determines whether the count value CNT has exceeded the threshold value TH.

### [Modification Example 2-2]

Although an abnormality in the synchronization signal XVS is detected in the above-described embodiment, the present disclosure is not limited thereto. Instead, for example, an abnormality in the synchronization signal XHS may be detected.

### 3. Application Example

Next, description is given of an application example of the imaging system described in the foregoing embodiment and the modification examples.

FIG. 16 illustrates a configuration example of an inspection system 90 to which the imaging system 2 according to the second embodiment or the like is applied. The inspection system 90 is configured to, for example, capture an image of an industrial product conveyed on a belt conveyor, and to perform inspection of the industrial product using the obtained image. The inspection system 90 includes a belt conveyor 91, imaging apparatuses 92A to 92C, and an inspection processor 93.

The belt conveyor 91 is configured to convey the industrial product to be inspected in a conveying direction A. It is possible to control a conveyance speed of the belt conveyor 91 on the basis of a control signal supplied from the inspection processor 93.

The imaging apparatuses 92A to 92C are configured to capture images of the industrial product conveyed by the belt conveyor 91. The imaging apparatuses 92A to 92C capture images of the industrial product from mutually different directions. Each of the imaging apparatuses 92A to 92C performs an imaging operation on the basis of the synchronization signal XVS supplied from the inspection processor 93, and supplies the image signal Spic indicating the image data of the captured image to the inspection processor 93.

The inspection processor 93 is configured to control inspection processing of the inspection system 90. The inspection processor 93 controls the conveyance speed of the belt conveyor 91 by supplying the control signal to the belt conveyor 91. The inspection processor 93 controls imaging timing of each of the imaging apparatuses 92A to 92C in capturing an image of the industrial product by supplying the synchronization signal XVS to the imaging apparatuses 92A to 92C. The inspection processor 93 inspects the industrial product on the basis of the image data indicated by the image signal Spic supplied from each of the imaging apparatuses 92A to 92C.

For example, each of the imaging apparatuses 92A to 92C corresponds to the imaging apparatus 30 illustrated in FIG. 11, for example. The inspection processor 93 corresponds to, for example, the image processing apparatus 40 illustrated in FIG. 11. It is possible for the abnormality detection circuit 49 provided in the inspection processor 93 to detect an abnormality in the synchronization signal XVS caused due to an abnormality in the signal path of the synchronization signal XVS from the inspection processor 93 to the imaging apparatuses 92A to 92C or a failure of the image signal generator 14 in the imaging apparatuses 92A to 92C.

### 4. Example of Practical Application to Mobile Body

The technique according to the present disclosure (present technology) is applicable to various products. For example, the technique according to the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, a drone, a vessel, a robot, etc.

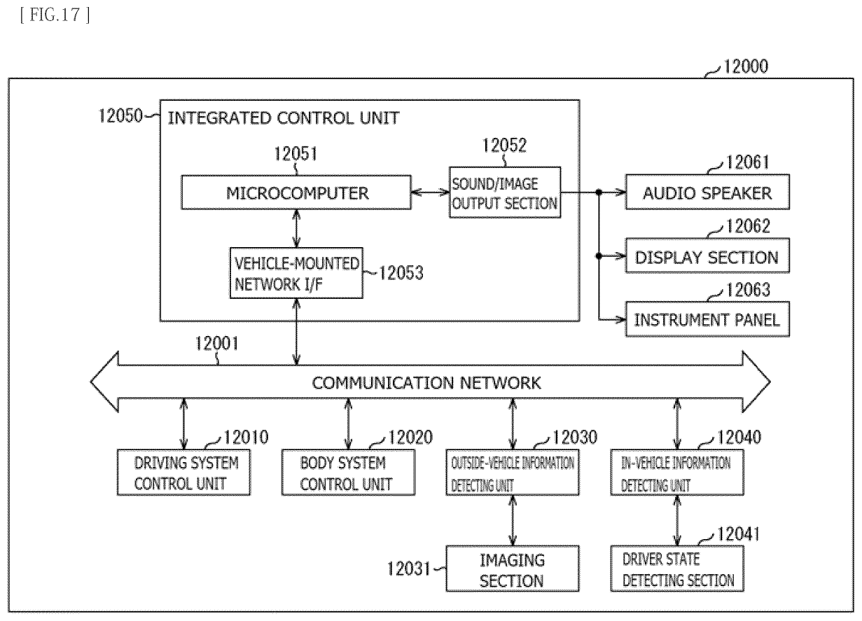

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

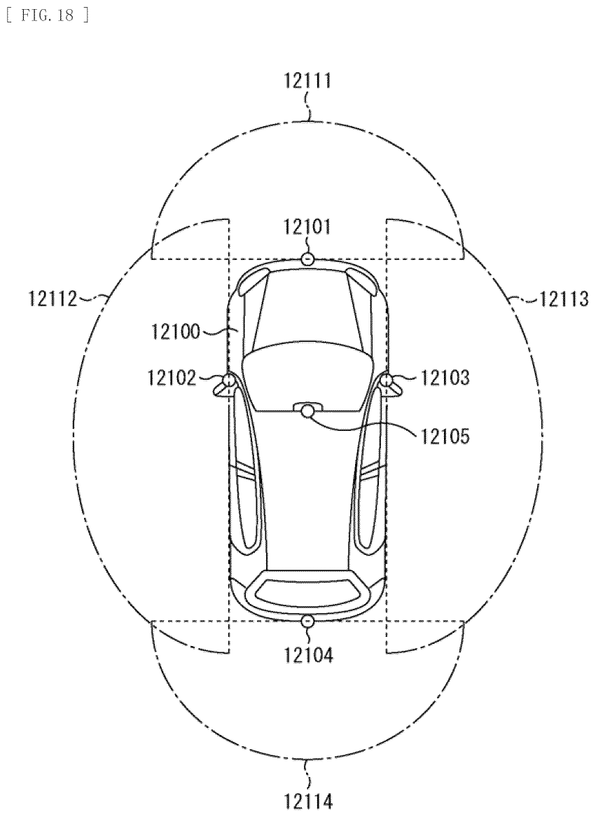

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the forgoing, described is one example of a vehicle control system to which the technique according to the present disclosure is applicable. The technique according to the present disclosure is applicable to the imaging section 12031 among the above-described components. In the imaging apparatus to be mounted on a vehicle, it is possible to improve reliability of the vehicle control system by detecting an abnormality in the synchronization signal. As a result, in the vehicle control system 12000, it is possible to improve the reliability in a collision avoidance or collision mitigation function of the vehicle, a following driving function based on the following distance, a vehicle speed maintaining driving function, a warning function of collision of the vehicle, a warning function of deviation of the vehicle from a lane, or the like.

The present technology has been described above with reference to some embodiments, the modification examples, the specific practical application examples thereof, and the application examples to electronic apparatuses, but the present technology is not limited to the embodiments and the like, and may be modified in a variety of ways.

For example, although an abnormality in the synchronization signal is detected by detecting a loss of the synchronization signal or a delay of the synchronization signal in each of the above-described embodiments and the like, the present disclosure is not limited thereto. Instead, for example, an abnormality in the synchronization signal may be detected in a case where a pulse of the synchronization signal appears earlier than a desired timing.

For example, although the SLVS-EC interface, the SLVS interface, and the MIPI are exemplified in each of the above-described embodiments and the like, the present disclosure is not limited thereto and may be applied to various interfaces. Further, the control data detected by the decoder is not limited to the examples illustrated in the embodiment and the modification examples, and various control data may be used.

It is to be noted that the effects described herein are merely illustrative and non-limiting, and other effects may be provided.

It is to be noted that the present technology may have the following configurations. According to the present technology having the following configuration, it is possible to detect an abnormality in the synchronization signal.

(1)

An abnormality detection circuit including:
a counter configured to, by performing a counting operation on a basis of pulses corresponding to a synchronization signal, detect a time length between two pulses corresponding to the synchronization signal; and
a determination circuit configured to determine an abnormality in the synchronization signal on a basis of a count value of the counter.
   (2)

The abnormality detection circuit according to (1), in which
the counter is configured to start the counting operation on a basis of a first pulse of the two pulses, and to stop the counting operation on a basis of a second pulse of the two pulses, and
the determination circuit is configured to determine the abnormality by determining whether the count value has exceeded a predetermined threshold value.
   (3)

The abnormality detection circuit according to (2), in which the synchronization signal includes the first pulse and the second pulse.

(4)

The abnormality detection circuit according to (2), further including
a decoder configured to decode control data included in an image signal corresponding to the synchronization signal and provided at a predetermined timing position in a cycle period corresponding to one cycle of the synchronization signal, in which
the decoder is configured to generate the first pulse on a basis of the control data in a first one of the cycle period, and to generate the second pulse on a basis of the control data in a second one of the cycle period after the first one of the cycle period.
   (5)

The abnormality detection circuit according to (2), further including:
a synchronization signal generation circuit configured to generate the synchronization signal; and
a decoder configured to decode control data included in an image signal corresponding to the synchronization signal and provided at a predetermined timing position in a cycle period corresponding to one cycle of the synchronization signal, in which
the synchronization signal includes the first pulse, and
the decoder is configured to generate the second pulse on a basis of the control data.
   (6)

The abnormality detection circuit according to (4) or (5), in which the control data is data indicating a frame beginning.

(7)

The abnormality detection circuit according to (4) or (5), in which the control data is data indicating whether data included in the image signal is effective.

(8)

An abnormality detection method including:
detecting, by performing a counting operation on a basis of pulses corresponding to a synchronization signal, a time length between two pulses corresponding to the synchronization signal; and
determining an abnormality in the synchronization signal on a basis of a count value of the counting operation.
   (9)

An imaging system including:
an imaging apparatus configured to perform an operation of imaging on a basis of a synchronization signal; and
an image processing apparatus configured to perform image processing on a basis of a result of the imaging by the imaging apparatus, in which
the image processing apparatus includes:
   a counter configured to, by performing a counting operation on a basis of pulses corresponding to the synchronization signal, detect a time length between two pulses corresponding to the synchronization signal; and
   a determination circuit configured to determine an abnormality in the synchronization signal on a basis of a count value of the counter.
      (10)

The imaging system according to (9), in which the image processing apparatus is configured to, in a case where the determination circuit determines the abnormality, stop the image processing.

This application claims the priority on the basis of Japanese Patent Application No. 2023-104877 filed on Jun. 27, 2023 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. An abnormality detection circuit comprising:
a counter configured to, by performing a counting operation on a basis of pulses corresponding to a synchronization signal, detect a time length between two pulses corresponding to the synchronization signal; and
a determination circuit configured to determine an abnormality in the synchronization signal on a basis of a count value of the counter.

2. The abnormality detection circuit according to claim 1, wherein
the counter is configured to start the counting operation on a basis of a first pulse of the two pulses, and to stop the counting operation on a basis of a second pulse of the two pulses, and
the determination circuit is configured to determine the abnormality by determining whether the count value has exceeded a predetermined threshold value.

3. The abnormality detection circuit according to claim 2, wherein the synchronization signal includes the first pulse and the second pulse.

4. The abnormality detection circuit according to claim 2, further comprising
a decoder configured to decode control data included in an image signal corresponding to the synchronization signal and provided at a predetermined timing position in a cycle period corresponding to one cycle of the synchronization signal, wherein
the decoder is configured to generate the first pulse on a basis of the control data in a first one of the cycle period, and to generate the second pulse on a basis of the control data in a second one of the cycle period after the first one of the cycle period.

5. The abnormality detection circuit according to claim 2, further comprising:
a synchronization signal generation circuit configured to generate the synchronization signal; and
a decoder configured to decode control data included in an image signal corresponding to the synchronization signal and provided at a predetermined timing position in a cycle period corresponding to one cycle of the synchronization signal, wherein
the synchronization signal includes the first pulse, and
the decoder is configured to generate the second pulse on a basis of the control data.

6. The abnormality detection circuit according to claim 4, wherein the control data is data indicating a frame beginning.

7. The abnormality detection circuit according to claim 4, wherein the control data is data indicating whether data included in the image signal is effective.

8. An abnormality detection method comprising:
detecting, by performing a counting operation on a basis of pulses corresponding to a synchronization signal, a time length between two pulses corresponding to the synchronization signal; and
determining an abnormality in the synchronization signal on a basis of a count value of the counting operation.

9. An imaging system comprising:
an imaging apparatus configured to perform an operation of imaging on a basis of a synchronization signal; and
an image processing apparatus configured to perform image processing on a basis of a result of the imaging by the imaging apparatus, wherein
the image processing apparatus includes:
a counter configured to, by performing a counting operation on a basis of pulses corresponding to the synchronization signal, detect a time length between two pulses corresponding to the synchronization signal; and
a determination circuit configured to determine an abnormality in the synchronization signal on a basis of a count value of the counter.

10. The imaging system according to claim 9, wherein the image processing apparatus is configured to, in a case where the determination circuit determines the abnormality, stop the image processing.
